(19) United States
(12) Patent Application Publication
(10) Pub. No.: US 2020/0131371 A1
(43) Pub. Date: Apr. 30, 2020

(54) COMPOUND, INK, RESIST COMPOSITION FOR COLOR FILTER, COLOR FILTER, HEAT SENSITIVE TRANSFER RECORDING SHEET AND TONER

(71) Applicant: CANON KABUSHIKI KAISHA, Tokyo (JP)

(72) Inventors: Taichi Shintou, Saitama-shi (JP); Koromo Shirota, Kawasaki-shi (JP); Ai Hayakawa, Ashigarakami-gun (JP); Tsuyoshi Santo, Yokohama-shi (JP)

(21) Appl. No.: 16/657,865

(22) Filed: Oct. 18, 2019

(30) Foreign Application Priority Data
Oct. 25, 2018 (JP) 2018-201044

(51) Int. Cl. C09B 55/00; G03F 7/00; G02F 1/1335; G03G 9/09

(52) U.S. Cl. CPC C09B 55/009; G03G 9/091; G02F 1/133514; G03F 7/0007

(57) ABSTRACT

A compound excellent in chroma, light resistance and solubility. The compound has a structure represented by Formula (1).

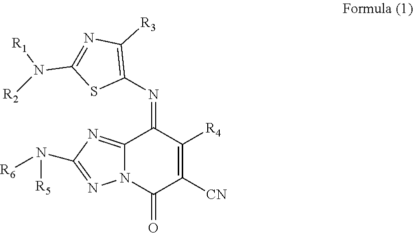

wherein R₁ and R₂ each independently represent a linear or branched alkyl group having 1 to 12 carbon atoms, R₃ represents a linear or branched alkyl group having 1 to 4 carbon atoms, an aryl group having a substituent, or an unsubstituted aryl group, and R₄ represents an alkyl group having 1 to 4 carbon atoms; and R₅ and R₆ each independently represent a linear, branched or cyclic alkyl group having 1 to 8 carbon atoms, an alkyl group having a hydroxyl group at the terminal, an aryl group having a substituent, or an unsubstituted aryl group; and R₅ and R₆ may be combined to form a heterocycle.

### BACKGROUND OF THE INVENTION

### Field of the Invention

The present disclosure relates to a compound; and an ink, a resist composition for a color filter, a color filter, a heat sensitive transfer recording sheet and a toner which use the compound.

### Description of the Related Art

Color filters are used in color displays using a liquid crystal. The color filter is indispensable for displaying a color of the liquid crystal display, and is an important component which affects performance of the liquid crystal display. As a conventional method for producing a color filter, there are known a dyeing method, a printing method, an ink jet method and a photoresist method. Among the methods, the photoresist method becomes mainstream because its spectral characteristics and color reproducibility are easily controlled, its resolution is high, and higher definition patterning is enabled.

In a production of color filters by the photoresist method, pigments have been generally used as colorants. However, color filters using pigments have many disadvantages such as a depolarizing effect (which means that polarization is lost), a decrease in a contrast ratio of the color display of the liquid crystal display, a decrease in lightness of the color filter, and a decrease in dispersion stability with respect to organic solvents and polymers. Then, a production method using a dye as a colorant has attracted attention. International Publication No. WO2013/187493 discloses a color filter using an azomethine-based dye as the colorant.

In addition, in recent years, along with widespread use of portable color display devices, a demand has increased rapidly for easy color printing of photographs which have been taken or have been processed, and of documents which have been created, with the use of the devices.

As a color printing system, an electrophotographic system, an inkjet system, a heat sensitive transfer recording system and the like are known. Among the systems, the heat sensitive transfer recording system is excellent as a method which can easily produce printed matters regardless of a surrounding environment, because the system can produce the printed matters by a dry process, and is small and excellent in portability of the printer. In the heat sensitive transfer recording system, dye contained in a transfer sheet and an ink composition for the transfer sheet is a very important material, because of affecting a speed of transfer recording, and an image quality and storage stability of a recorded matter. Japanese Patent Application Laid-Open No. 2000-006540 discloses an example in which the light resistance is improved by the use of an azomethine-based dye as a dye that is used in the heat sensitive transfer recording system.

In addition, also in a field of color toners which are used in an electrophotographic system, an example is reported in which dye is used in place of pigment that is conventionally used as a colorant, in order to enhance color developability. As an example, German Patent Publication No. 4217973 discloses an example in which an azomethine-based dye is used as a colorant of a toner.

Furthermore, digital textile printing using an ink jet system or an electrophotographic system is spreading in the market as a method which can provide a textile printed product with low energy and at low cost. In particular, a system of dyeing synthetic fibers such as polyester with a sublimation dye has recently attracted attention in terms of simplification of the process and elimination of drainage. In this application, it is necessary for the dye to sublime; phthalocyanine having a large molecular weight cannot be used, and an anthraquinone type is used for a cyan color; but there has been a disadvantage in color development.

A disadvantage of the azomethine-based dye described in the above documents is that chroma is low and aggregation tends to occur.

### SUMMARY OF THE INVENTION

The present disclosure is directed to providing a compound excellent in chroma, light resistance and solubility. In addition, the present disclosure is directed to providing an ink, a resist composition for a color filter, a color filter, a heat sensitive transfer recording sheet and a toner which are excellent in chroma and light resistance, by using the compound.

According to the present disclosure, there is provided a compound having a structure which is represented by following Formula (1).

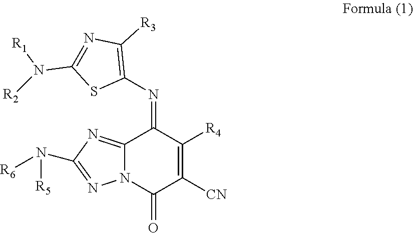

wherein
R₁ and R₂ each independently represent a linear or branched alkyl group having 1 to 12 carbon atoms,
R₃ represents an alkyl group having 1 to 4 carbon atoms, an aryl group having a substituent or an unsubstituted aryl group,
R₄ represents an alkyl group having 1 to 4 carbon atoms, and
R₅ and R₆ satisfy the following specifications (i) or (ii):
(i) R₅ and R₆ each independently represent a linear, branched or cyclic alkyl group having 1 to 8 carbon atoms, an alkyl group having a hydroxyl group at the terminal, an aryl group having a substituent, or an unsubstituted aryl group; and
(ii) R₅ and R₆ are combined to form a heterocycle, and R₅ and R₆ each represent an atomic group necessary for forming a heterocycle.

In addition, according to the present disclosure, there is provided an ink that contains a medium and a compound which exists in a dissolved or dispersed state in the medium, wherein the compound is the above compound.

In addition, according to the present disclosure, there is provided a resist composition for a color filter, which contains the above compound.

In addition, according to the present disclosure, there is provided a color filter that contains the above compound.

In addition, according to the present disclosure, there is provided a heat sensitive transfer recording sheet that has a base material and a coloring material layer formed on the base material, wherein the above compound is contained in the coloring material layer.

In addition, according to the present disclosure, there is provided a toner that contains a binder resin and a colorant, wherein the colorant contains the above compound.

According to the present disclosure, there is provided a compound that is excellent in chroma, light resistance and solubility. In addition, according to the present disclosure, there is provided the ink, the resist composition for the color filter, the color filter, the heat sensitive transfer recording sheet and the toner, which are excellent in the chroma and the light resistance.

Further features of the present disclosure will become apparent from the following description of exemplary embodiments.

### DESCRIPTION OF THE EMBODIMENTS

Embodiments of the present disclosure will be described in detail below, but the technical scope of the present invention is not limited to the embodiments.

The present inventors have made an extensive investigation so as to solve the above disadvantages, and as a result, have found that a compound having a structure represented by following Formula (1) is excellent in chroma, light resistance and solubility.

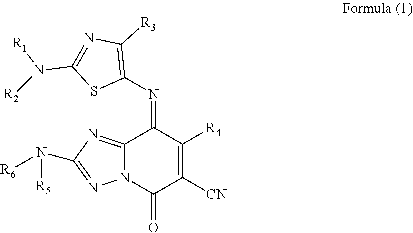

wherein

R₁ and R₂ each independently represent a linear or branched alkyl group having 1 to 12 carbon atoms, R₃ represents an alkyl group having 1 to 4 carbon atoms, an aryl group having a substituent, or an unsubstituted aryl group,

R₄ represents an alkyl group having 1 to 4 carbon atoms, and

R₅ and R₆ satisfy the following specifications (i) or (ii):

(i) R₅ and R₆ each independently represent a linear, branched or cyclic alkyl group having 1 to 8 carbon atoms, an alkyl group having a hydroxyl group at the terminal, an aryl group having a substituent, or an unsubstituted aryl group; and

(ii) R₅ and R₆ are combined to form a heterocycle, and R₅ and R₆ each represent an atomic group necessary for forming a heterocycle.

A compound having a structure similar to the structure represented by above Formula (1) does not necessarily have the same characteristics as the compound having the structure represented by above Formula (1). For example, when the substituent at the 2-position of the [1,2,4]triazolo[1,5-a]pyridine ring has a branched structure such as a 2-ethylhexyl group, the solubility of the compound in the solvent decreases, and the compound not only tends to easily condense but also has low light resistance, which has been confirmed in the present experiment. On the other hand, when the substituent at the 2-position of the [1,2,4]triazolo[1,5-a] pyridine ring is an amino group as in above Formula (1) of the present disclosure, the structure of the compound keeps a three-dimensional twisted structure. Because of this, it is considered that an intramolecular interaction of the compound or an intermolecular interaction among the compound molecules is suppressed, and the aggregation can be controlled. For this reason, it is considered that the compound has become excellent in the chroma, the light resistance and the solubility.

In addition, it has been found that by using the compound represented by Formula (1), an ink, a resist composition for a color filter, a color filter, a heat sensitive transfer recording sheet and a toner can be obtained, which are excellent in the chroma and the light resistance.

Firstly, the compound represented by above Formula (1) will be described.

In Formula (1), the linear or branched alkyl group having 1 to 12 carbon atoms in R₁ and R₂ is not limited in particular, but examples thereof include the following: a methyl group, an ethyl group, an n-propyl group, an iso-propyl group, an n-butyl group, a sec-butyl group, a tert-butyl group, an n-hexyl group, an n-heptyl group, an n-octyl group, an n-nonyl group, an n-decyl group, an n-undecyl group, an n-dodecyl group, a 2-ethylhexyl group and a cyclohexyl group.

Among the groups, an alkyl group having 8 carbon atoms is preferable, and in particular, the branched alkyl group such as the 2-ethylhexyl group is more preferable, from the viewpoint that the compound becomes excellent in the chroma, the light resistance and the solubility.

In Formula (1), the alkyl group in R₃ is not limited in particular, but includes linear and branched alkyl groups having 1 to 4 carbon atoms. Specifically, examples thereof include primary alkyl groups such as a methyl group, an ethyl group, an n-propyl group and an n-butyl group; secondary alkyl groups such as an iso-propyl group and a sec-butyl group; and tertiary alkyl groups such as a tert-butyl group. Among the alkyl groups, the tert-butyl group is preferable, from the viewpoint that the compound becomes excellent in the chroma, the light resistance and the solubility.

In Formula (1), the aryl group in R₃ is not limited in particular, but includes an aryl group having a substituent having 6 to 20 carbon atoms or an unsubstituted aryl group. The substituent includes an alkyl group and an alkoxy group. Note that when the aryl group has the substituent, the above number of the carbon atoms represents the number containing the number of the carbon atoms of the substituent. In addition, the number of the substituents may be one or plural. Specifically, examples of the aryl group which has a substituent having 6 to 20 carbon atoms or the unsubstituted aryl group include the following: a phenyl group, a 4-methylphenyl group, a 2,4-dimethylphenyl group, a 2,6-dimethylphenyl group, a 3,5-dimethylphenyl group, a 2,4,6-trimethylphenyl group, pentamethyl phenyl group, a 4-methoxyphenyl group, a 2,6-dimethoxyphenyl group, a 2,4-dimethoxyphenyl group, a 3,5-dimethoxyphenyl group, a 2,4,6-tridimethoxyphenyl group and a naphthyl group. Among the aryl groups, the phenyl group having the substituent or the unsubstituted phenyl group is preferable, and the unsubstituted phenyl group is more preferable, from the viewpoint that the compound becomes excellent in the chroma, the light resistance and the solubility.

It is preferable that among the groups, R₃ is the unsubstituted phenyl group, from the viewpoint that the compound becomes excellent in the chroma, the light resistance and the solubility.

In Formula (1), a linear or branched alkyl group having 1 or more and 4 or less carbon atoms in R₄ is not limited in particular, but examples thereof include the following: a methyl group, an ethyl group, an n-propyl group, an iso-propyl group, an n-butyl group, a sec-butyl group and a tert-butyl group. Among the groups, linear alkyl groups such as the methyl group, the ethyl group and the n-butyl group are preferable, and the methyl group is particularly preferable.

In Formula (1), the linear, branched or cyclic alkyl group having 1 to 8 carbon atoms in R₅ and R₆ is not limited in particular, but examples thereof include the following: a methyl group, an ethyl group, an n-propyl group, an iso-propyl group, an n-butyl group, a sec-butyl group, a tert-butyl group, a pentyl group, a hexyl group, a heptyl group, an octyl group, a cyclopropyl group, a cyclobutyl group, a cyclopentyl group, a cyclohexyl group, a methyl cyclohexyl group, a 2-ethylpropyl group, and a 2-ethylhexyl group. Among the alkyl groups, the methyl group and the ethyl group are preferable.

In Formula (1), the alkyl group having a hydroxyl group at the terminal in R₅ and R₆ is not limited in particular, but examples thereof include the following: a hydroxymethyl group, a hydroxyethyl group, a hydroxyl propyl group, and a hydroxyl butyl group. Among the alkyl groups, the hydroxyl ethyl group is preferable.

In Formula (1), the aryl group in R₅ and R₆ is not limited in particular, but includes an aryl group having a substituent having 6 to 20 carbon atoms and the unsubstituted aryl group. The substituent includes an alkyl group and an alkoxy group. Note that when the aryl group has the substituent, the above number of the carbon atoms represents the number containing the number of the carbon atoms of the substituent. In addition, the number of the substituents may be one or plural. Specifically, examples of the aryl group which has the substituent having 6 to 20 carbon atoms or the unsubstituted aryl group include a phenyl group, a 4-methylphenyl group and a 4-methoxyphenyl group.

In Formula (1), the heterocycle formed by the combination of R₅ and R₆ is not limited in particular, but examples thereof include a piperidine ring and a morpholine ring.

Next, a method for producing the compound having the structure represented by above Formula (1) will be described. The compound having the structure represented by above Formula (1) can be synthesized with reference to a known method described in Japanese Patent Application Laid-Open No. H08-245896. One example of the production method is shown below, but the production method of the compound which has the structure represented by above Formula (1) is not limited to the example.

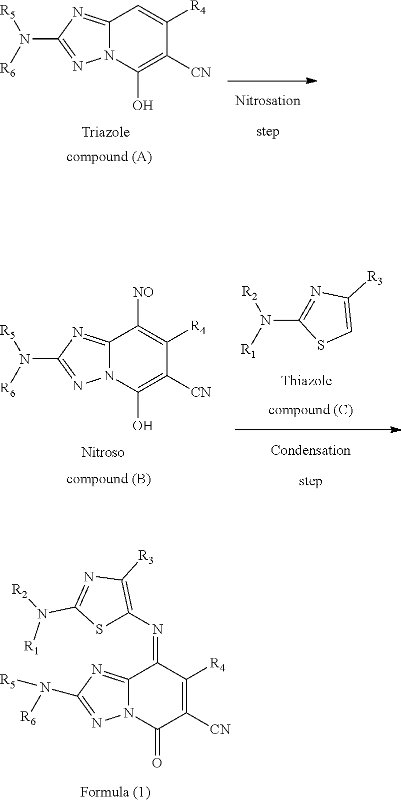

Note that R₁ to R₆ in each compound in the above reaction formula represent the same groups as those described in the above. In the compound having the structure represented by above Formula (1), cis and trans isomers exist, but both are within the scope of the present disclosure; and the compound having the structure represented by Formula (1) may be a mixture of the isomers.

The compound having the structure represented by above Formula (1) can be produced through a nitrosation step of inducing a triazole compound (A) into a nitroso compound, and a condensation step of subjecting the above nitroso compound to a condensation reaction with a thiazole compound (C).

[Condensation step]

The Above Condensation Step Will be Described.

Preferred examples of the triazole compound (A) are shown in the following (A-1) to (A-10), but the present invention is not limited to the examples.

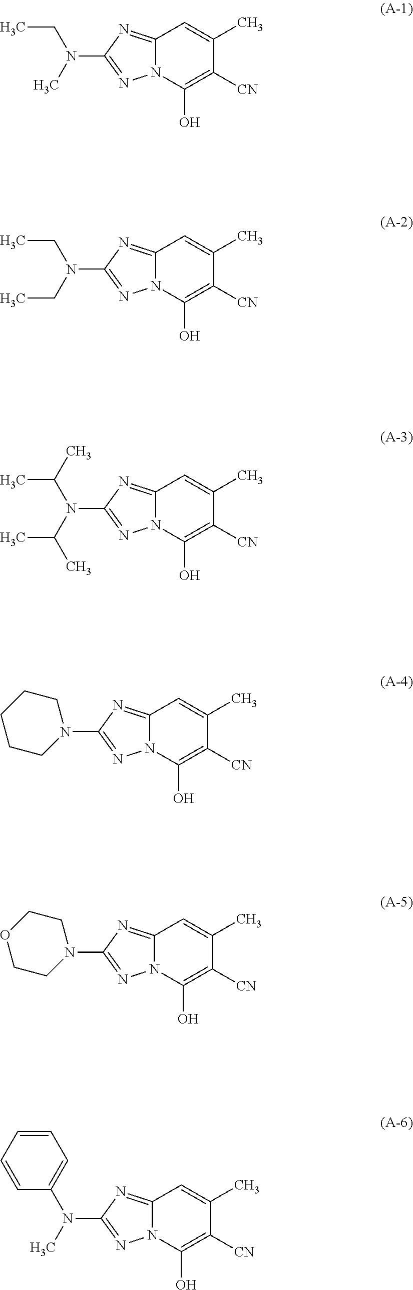 [SMILES: CCN(C)c1nc2cc(C)c(C#N)c(O)n2n1 ; CCN(CC)c1nc2cc(C)c(C#N)c(O)n2n1 ; Cc1cc2nc(N(C(C)C)C(C)C)nn2c(O)c1C#N ; Cc1cc2nc(N3CCCCC3)nn2c(O)c1C#N ; Cc1cc2nc(N3CCOCC3)nn2c(O)c1C#N ; Cc1cc2nc(N(C)c3ccccc3)nn2c(O)c1C#N]

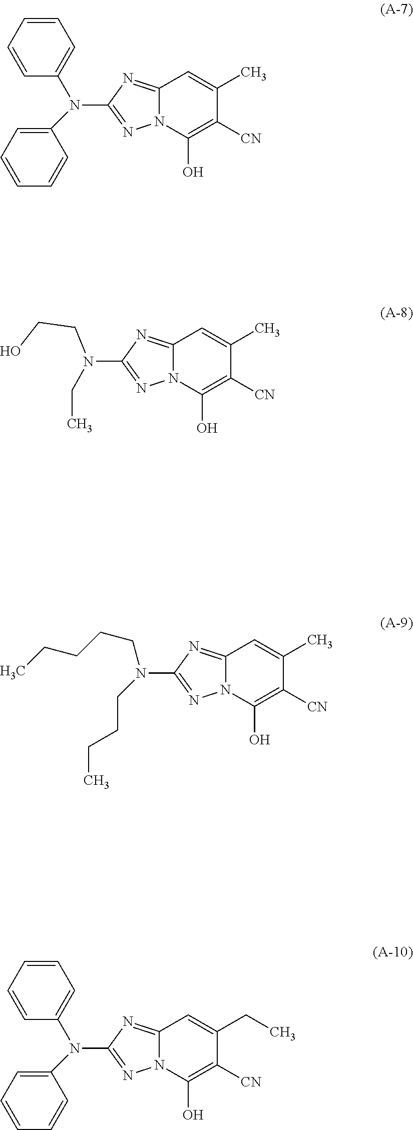 [SMILES: Cc1cc2nc(N(c3ccccc3)c3ccccc3)nn2c(O)c1C#N ; CCN(CCO)c1nc2cc(C)c(C#N)c(O)n2n1 ; CCCCCN(CCCC)c1nc2cc(C)c(C#N)c(O)n2n1 ; CCc1cc2nc(N(c3ccccc3)c3ccccc3)nn2c(O)c1C#N]

Preferred examples of the thiazole compound (C) are shown in the following (C-1) to (C-8), but the present invention is not limited to the examples.

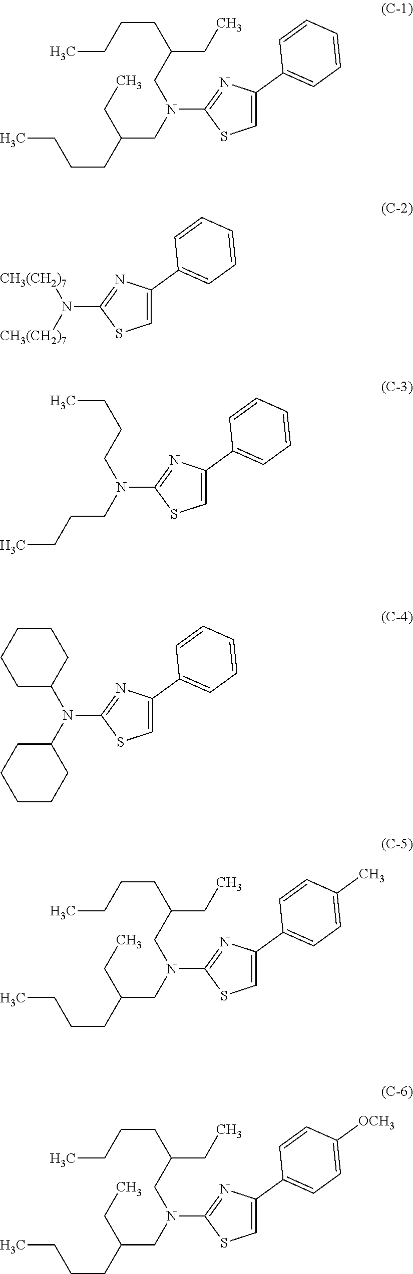

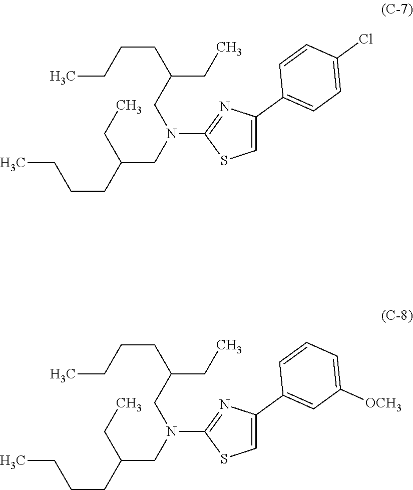 [SMILES: CCCCC(CC)CN(CC(CC)CCCC)c1nc(-c2ccc(Cl)cc2)cs1 ; CCCCC(CC)CN(CC(CC)CCCC)c1nc(-c2cccc(OC)c2)cs1]

The condensation reaction can be carried out without a solvent, but is preferably carried out in the presence of a solvent. The solvent is not particularly limited as long as the solvent does not inhibit the reaction, and examples thereof include the following: chloroform, dichloromethane, N,N-dimethylformamide, toluene, xylene, tetrahydrofuran, dioxane, acetonitrile, ethyl acetate, methanol, ethanol and isopropanol. These solvents may be used singly or may be used in a form of a mixture of two or more. A mixing ratio at the time when the mixture is used can be arbitrarily determined. It is preferable for the amount of the above solvent to be used for the reaction to be 0.1% by mass or more and 1000% by mass or less with respect to the thiazole compound (C), and is more preferable to be 1.0% by mass or more and 150% by mass or less.

It is preferable for a reaction temperature of the present condensation reaction to be in a range of −80° C. or higher and 250° C. or lower, and is more preferable to be −20° C. or higher and 150° C. or lower. The present condensation reaction usually ends within 24 hours.

In addition, it is preferable in the present condensation reaction to use an acid or a base in order to promote the reaction. Specifically, examples of the acid include: inorganic acids such as hydrochloric acid, sulfuric acid and phosphoric acid; and organic acids such as p-toluene sulfonic acid, formic acid, acetic acid, propionic acid and trifluoroacetic acid. In addition, it is also possible to use weakly acidic salts such as ammonium formate and ammonium acetate, similarly to the above acids. Among the acids and the salts, the p-toluene sulfonic acid, and the ammonium formate or the ammonium acetate are preferable. It is preferable for the amount of the above acid to be used to be 0.01% by mass or more and 20% by mass or less with respect to the thiazole compound (C), and is more preferable to be 0.1 to 5% by mass.

In addition, specifically, examples of the base include the following: organic bases such as pyridine, 2-methylpyridine, piperidine, diethylamine, diisopropylamine, triethylamine, phenylethylamine, isopropyl ethylamine, methylaniline, 1,4-diazabicyclo-[2.2.2]octane (DABCO), tetrabutylammonium hydroxide, 1,8-diazabicyclo-[5.4.0]undecene (DBU); organic metals such as n-butyllithium and tert-butylmagnesium chloride; inorganic bases such as sodium borohydride, metallic sodium, potassium hydride and calcium oxide; and metal alkoxides such as potassium tert-butoxide, sodium tert-butoxide and sodium ethoxide. Among the bases, the triethylamine or the piperidine is preferable, and the triethylamine is more preferable. It is preferable for the amount of the above base to be used to be 0.1% by mass or more and 20% by mass or less with respect to the thiazole compound (C), and is more preferable to be 0.2% by mass or more and 5% by mass or less. In addition, it is also possible to use weakly basic salts such as potassium acetate, similarly to the above bases.

After the condensation reaction has been completed, the condensate is subjected to post-treatment according to a post-treatment method which is usually used in organic synthesis reactions, and the resultant condensate is subjected to purification such as a liquid separation operation, recrystallization, reprecipitation and column chromatography, as needed. By the above steps, the compound of the present disclosure having a structure represented by Formula (1) can be obtained at high purity.

Examples of compounds which are preferable as the compound of the present disclosure having the structure represented by Formula (1) are shown in the following (1-1) to (1-9), but the present invention is not limited to the examples.

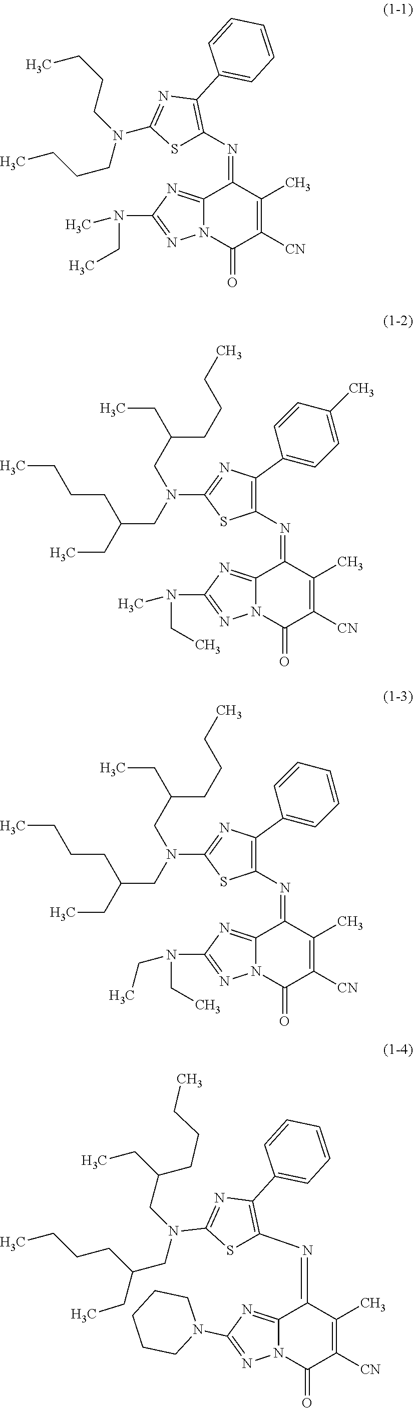

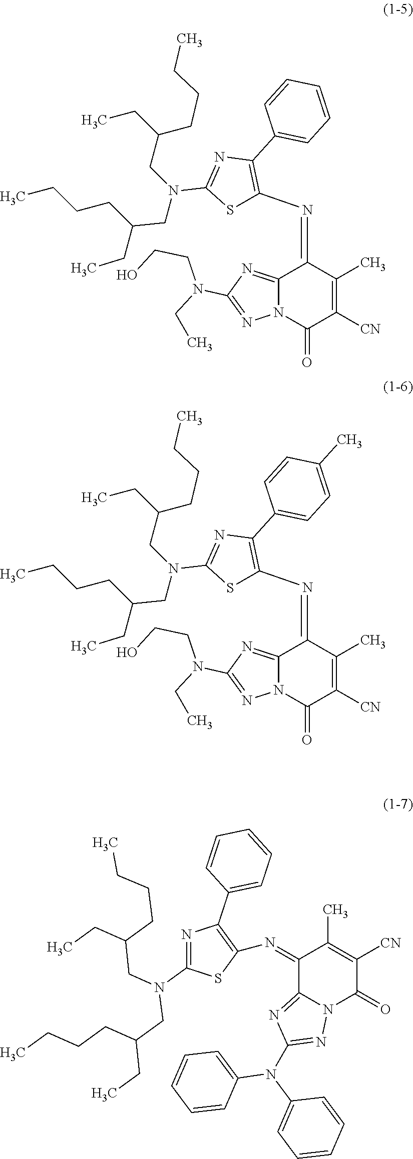 [SMILES: CCCCC(CC)CN(CC(CC)CCCC)c1nc(-c2ccccc2)c(/N=C2/C(C)=C(C#N)C(=O)n3nc(N(CC)CCO)nc32)s1 ; CCCCC(CC)CN(CC(CC)CCCC)c1nc(-c2ccc(C)cc2)c(/N=C2/C(C)=C(C#N)C(=O)n3nc(N(CC)CCO)nc32)s1 ; CCCCC(CC)CN(CC(CC)CCCC)c1nc(-c2ccccc2)c(/N=C2/C(C)=C(C#N)C(=O)n3nc(N(c4ccccc4)c4ccccc4)nc32)s1]

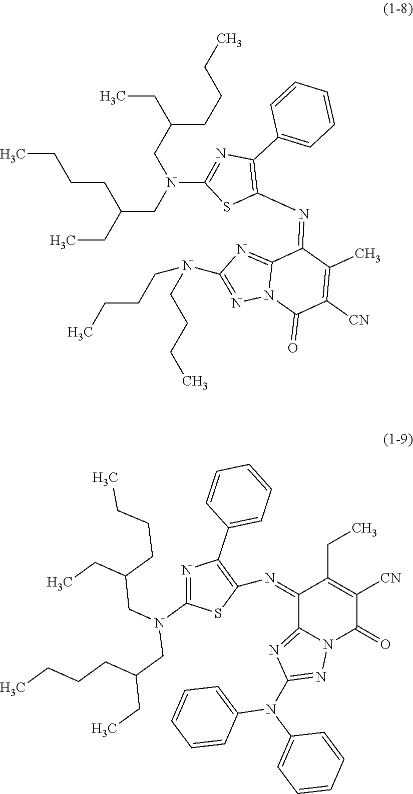

The compounds having the structure represented by above Formula (1) may be used singly, or two or more thereof may be used in combination so as to adjust the color tone or the like according to the application. Furthermore, the compound can be used also in combination with known pigment or dye. The known pigment or dye to be combined may be two or more.

The ink, the resist composition for the color filter, the color filter, the heat sensitive transfer recording sheet and the toner which use the compound represented by above Formula (1) will be sequentially described below.

<Ink>

Firstly, the ink according to the present disclosure will be described. The compound represented by Formula (1) has high chroma, high light resistance and high solubility, and accordingly is suitable as a colorant of the ink. The ink of the present disclosure contains a medium, and the compound represented by Formula (1) as the colorant. The compound exists in a state of being dissolved or dispersed in the medium. In the ink of the present disclosure, constituent components other than the compound represented by above Formula (1) are appropriately selected according to the application of the ink. Moreover, an additive and the like may be appropriately added in a range that does not inhibit the characteristics in each of various applications.

The ink of the present disclosure is also suitable as an ink for a transfer sheet for a heat sensitive transfer recording system printer, an ink for printing, paint, an ink for writing materials, and an ink for textile printing.

When the ink of the present disclosure is used as the ink for textile printing, a textile which can be used for the textile printing is not limited in particular as long as the textile can be dyed, but examples of the textile include textiles formed of fiber containing any of polyester, acetate and triacetate. The textile may have any form of a woven fabric, a knitted fabric, a non-woven fabric and the like. In addition, a textile can be used which is formed of cotton, silk, hemp, polyurethane, acrylic, nylon, wool and rayon fibers, or a textile can also be used in which two or more of the fibers are combined.

It is preferable that the thickness of a yarn constituting the textile is in a range of 10 denier or more and 100 denier or less. The thickness of a fiber constituting the yarn is not limited in particular, but is preferably 1 denier or less.

The ink of the present disclosure can be prepared in the following way.

The compound of the present disclosure and other colorant, emulsifier, resin and the like, as needed, are gradually added into a medium with stirring, and are fully acclimated to the medium. Furthermore, a mechanical shearing force is applied to the above mixture with the use of a dispersing machine to stably dissolve or finely disperse the same, and thereby the ink of the present disclosure can be obtained.

[Medium]

In the present disclosure, “medium” means water or an organic solvent. When the organic solvent is used as the medium, the type of the organic solvent is selected according to the purpose or application of the ink, and is not limited in particular. Examples of the organic solvent include the following: alcohols such as methanol, ethanol, denatured ethanol, isopropanol, n-butanol, isobutanol, tert-butanol, sec-butanol, 2-methyl-2-butanol, 3-pentanol, octanol, benzyl alcohol, and cyclohexanol; glycols such as methyl cellosolve, ethyl cellosolve, diethylene glycol, and diethylene glycol monobutyl ether; ketones such as acetone, methyl ethyl ketone, and methyl isobutyl ketone; esters such as ethyl acetate, butyl acetate, ethyl propionate, and cellosolve acetate; aliphatic hydrocarbons such as hexane, octane, petroleum ether, and cyclohexane; aromatic hydrocarbons such as benzene, toluene and xylene; halogenated hydrocarbons such as carbon tetrachloride, trichlorethylene and tetrabromoethane; ethers such as diethyl ether, dimethyl glycol, trioxane and tetrahydrofuran; acetals such as methylal, and diethyl acetal; organic acids such as formic acid, acetic acid, and propionic acid; and sulfur- or nitrogen-containing organic compounds such as nitrobenzene, dimethylamine, monoethanolamine, pyridine, dimethyl sulfoxide, and dimethylformamide.

As the organic solvent, a polymerizable monomer can also be used. The polymerizable monomer includes an addition polymerizable monomer and a condensation polymerizable monomer, and the addition polymerizable monomer is preferable. Specifically, examples of the polymerizable monomer include the following: styrene-based monomers such as styrene, α-methylstyrene, α-ethylstyrene, o-methylstyrene, m-methylstyrene, p-methylstyrene, o-ethylstyrene, m-ethylstyrene and p-ethylstyrene; acrylate-based monomers such as methyl acrylate, ethyl acrylate, propyl acrylate, butyl acrylate, octyl acrylate, dodecyl acrylate, stearyl acrylate, behenyl acrylate, 2-ethylhexyl acrylate, dimethylaminoethyl acrylate, diethylaminoethyl acrylate, acrylonitrile, and acrylic acid amide; methacrylate-based monomers such as methyl methacrylate, ethyl methacrylate, propyl methacrylate, butyl methacrylate, octyl methacrylate, dodecyl methacrylate, stearyl methacrylate, behenyl methacrylate, 2-ethylhexyl methacrylate, dimethylaminoethyl methacrylate, diethylaminoethyl methacrylate, methacrylonitrile, and methacrylic acid amide; olefin-based monomers such as ethylene, propylene, butylene, butadiene, isoprene, isobutylene and cyclohexene; halogenated vinyl-based monomers such as vinyl chloride, vinylidene chloride, vinyl bromide and vinyl iodide; vinyl ester-based monomers such as vinyl acetate, vinyl propionate and vinyl benzoate; vinyl ether-based monomers such as vinyl methyl ether, vinyl ethyl ether, and vinyl isobutyl ether; and vinyl ketone-based monomers such as vinyl methyl ketone, vinyl hexyl ketone, and methyl isopropenyl ketone. These monomers may be used singly or in combinations of two or more, as needed.

[Dispersant]

When water is used as the medium of the ink according to the present disclosure, a dispersant may be added as needed, in order to obtain a good dispersion stability of the colorant. The dispersant is not limited in particular, but includes a cationic surfactant, an anionic surfactant and a nonionic surfactant.

Examples of the above cationic surfactant include the following: dodecyl ammonium chloride, dodecyl ammonium bromide, dodecyl trimethyl ammonium bromide, dodecyl pyridinium chloride, dodecyl pyridinium bromide, and hexadecyl trimethyl ammonium bromide.

Examples of the above anionic surfactant include the following: fatty acid soaps such as sodium stearate and sodium dodecanoate; and sodium dodecyl sulfate, sodium dodecylbenzene sulfate, sodium lauryl sulfate, naphthalene, and a formalin condensate of (3-naphthalene sulfonic acid.

Examples of the above nonionic surfactant include the following: dodecyl polyoxyethylene ether, hexadecyl polyoxyethylene ether, nonylphenyl polyoxyethylene ether, lauryl polyoxyethylene ether, sorbitan monooleate polyoxyethylene ether, and monodecanoyl sucrose.

[Colorant]

As the colorant constituting the ink of the present disclosure, the compound represented by Formula (1) is used, and the compounds may be used singly or in combinations of two or more. In addition, other colorants such as a well-known dye may be used in combination in a range that does not inhibit the solubility or dispersibility of the compound to the medium. The other colorants which can be used in combination are not limited in particular, but examples of the colorants include a condensed azo compound, a metal azo complex and a methine compound.

It is preferable for the content of the above colorant to be 1.0 part by mass to 30 parts by mass with respect to 1000 parts by mass of the medium, is more preferable to be 2.0 parts by mass to 20 parts by mass, and is particularly preferable to be 3.0 parts by mass to 15 parts by mass. If the content is within the above range, the ink acquires a sufficient coloring power, and the dispersibility of the colorant becomes good.

[Resin]

The ink of the present disclosure may further contain a resin. The type of resin is determined according to the purpose and/or application of the ink, and is not limited in particular. Examples of the resin include the following: a styrene-based polymer, an acrylic acid-based polymer, a methacrylic acid-based polymer, a polyester resin, polyvinyl ether resin, a polyvinyl methyl ether resin, a polyvinyl alcohol resin, a polyvinyl butyral resin, a polyurethane resin and a polypeptide resin. These resins may be used singly or in combinations of two or more, as needed.

The dispersing machine is not limited in particular, but media type dispersing machines such as a rotary shear type homogenizer, a ball mill, a sand mill and an attritor, and a high-pressure opposed collision type of dispersing machine can be used.

As described above, the ink of the present disclosure contains the compound represented by Formula (1), and accordingly can provide an ink excellent in the chroma and the light resistance.

<Heat Sensitive Transfer Recording Sheet>

Next, the heat sensitive transfer recording sheet according to the present disclosure will be described. The compound of the present disclosure is excellent in the chroma, the light resistance and the solubility, and accordingly can be preferably used for the heat sensitive transfer recording sheet.

The heat sensitive transfer recording sheet according to the present disclosure has a base material, and a coloring material layer that is formed of a film of a composition containing the compound of the present disclosure, which has been formed on the base material. The coloring material layer has at least a yellow layer, a magenta layer and a cyan layer.

In a heat sensitive transfer recording method, the heat sensitive transfer recording sheet is heated by the use of a heating unit such as a thermal head, in a state in which the coloring material layer of the heat sensitive transfer recording sheet and an image receiving sheet provided with a coloring material receiving layer on the surface are overlapped. By such a process, the coloring material in the heat sensitive transfer recording sheet is transferred to the image receiving sheet, and the image is formed.

The cyan layer of the above coloring material layer is formed basically by the above ink of the present disclosure being applied to the base material sheet and then being dried. The heat sensitive transfer recording sheet will be described further in detail below.

A coloring material containing the compound represented by Formula (1), a binder resin, and a surfactant and a wax as needed are gradually added into a medium with stirring, and are sufficiently acclimated to the medium. Subsequently, a mechanical shearing force is applied to the above mixture by the use of a dispersing machine to stably dissolve or disperse the above compositions into a state of fine particles, and the ink is prepared. The ink is applied to a base film which is the base material, and is dried, and thereby the coloring material layer is formed. Furthermore, if necessary, a transferable protective layer, a heat-resistant slipping layer and the like are formed which will be described later, and thereby the heat sensitive transfer recording sheet of the present disclosure can be obtained. Note that the heat sensitive transfer recording sheet of the present disclosure is not limited to the heat sensitive transfer recording sheet which has been produced by the above production method. Each component to be used for the coloring material layer will be described in detail below.

[Coloring Material]

As the coloring material, the compound represented by Formula (1) is used, and the compounds may be used singly or in combinations of two or more. In addition, a known coloring material which is conventionally used for thermal transfer can also be used in combination. The coloring material to be used in combination needs to be designed in consideration of hue, printing sensitivity, light resistance, the storage stability, solubility in a binder resin, and the like. The amount of the coloring material to be used is 1 part by mass to 150 parts by mass with respect to 100 parts by mass of the binder resin which is contained in the coloring material layer, and is preferably 50 parts by mass to 120 parts by mass, from the viewpoint of dispersibility of the coloring material in the dispersion liquid. Note that when two or more of coloring materials are mixed and used, the total amount is preferably in the above range.

[Binder Resin]

As the binder resin, not limited in particular, but the following resins are preferable: water-soluble resins such as a cellulose resin, a polyacrylic acid resin, a starch resin and an epoxy resin; and organic solvent-soluble resins such as a polyacrylate resin, a polymethacrylate resin, a polystyrene resin, a polycarbonate resin, a polyether sulfone resin, a polyvinyl butyral resin, an ethyl cellulose resin, an acetyl cellulose resin, a polyester resin, an AS resin and a phenoxy resin. These resins may be used singly or in combinations of two or more, as needed.

[Surfactant]

A surfactant may be added to the heat sensitive transfer recording sheet of the present disclosure so that the sheet shows sufficient slipperiness when being heated by a thermal head (at the time of printing).

[Wax]

A wax may be added to the heat sensitive transfer recording sheet of the present disclosure so that the sheet shows sufficient slipperiness when being not heated by the thermal head. The waxes which can be added include a polyethylene wax, a paraffin wax, and a wax of a fatty acid ester, but are not limited to these waxes.

In addition to the above additives, it is acceptable to add an ultraviolet absorber, an antiseptic, an antioxidant, an antistatic agent, a viscosity modifier and the like to the heat sensitive transfer recording sheet of the present disclosure, as needed.

[Medium]

The medium to be used for the preparation of a dispersion when the coloring material layer is formed is not limited in particular, but examples thereof include water or organic solvents. Preferable organic solvents include the following: alcohols such as methanol, ethanol, isopropanol and isobutanol; cellosolves such as methyl cellosolve and ethyl cellosolve; aromatic hydrocarbons such as toluene, xylene and chlorobenzene; esters such as ethyl acetate and butyl acetate; ketones such as acetone, methyl ethyl ketone, methyl isobutyl ketone and cyclohexanone; halogenated hydrocarbons such as methylene chloride, chloroform and trichloroethylene; ethers such as tetrahydrofuran and dioxane; and N,N-dimethylformamide and N-methylpyrrolidone. The above organic solvents may be used singly or in combinations of two or more, as needed.

[Base Material]

Next, a base material constituting the heat sensitive transfer recording sheet will be described. The base material is not limited in particular as long as the base material is a film which supports the above coloring material layer and has a certain degree of heat resistance and strength, and a known material can be used. Examples of the base material include the following: a polyethylene terephthalate film, a polyethylene naphthalate film, a polycarbonate film, a polyimide film, a polyamide film, an aramid film, a polystyrene film, a 1,4-polycyclohexylenedimethylene terephthalate film, a polysulfone film, a polypropylene film, a polyphenylene sulfide film, a polyvinyl alcohol film, cellophane, a cellulose derivative, a polyethylene film, a polyvinyl chloride film, a nylon film, a condenser paper and a paraffin paper. Among the above materials, the polyethylene terephthalate (hereinafter also referred to as PET) film is preferable, from the viewpoints of mechanical strength, solvent resistance and economy.

The thickness of the above base material is 0.5 μm to 50 μm, and is preferably 3 μm to 10 μm, from the viewpoint of transferability.

When a dye ink is applied onto the base material so as to form the coloring material layer, the wettability and adhesiveness of the coating liquid are apt to be insufficient. Because of this, it is preferable that the surface (formation surface) of the base material, on which the above coloring material layer is formed, is subjected to pre-bonding treatment, as needed. The surface on which the coloring material layer is formed may be one surface or both surfaces of the base material. The pre-bonding treatment is not limited in particular, but examples thereof include ozone treatment, corona discharge treatment, ultraviolet treatment, plasma treatment, low temperature plasma treatment, primer treatment and chemical treatment. In addition, a plurality of these treatments may be combined with each other, and be performed.

An adhesive layer may be formed on the base material, as the above pre-bonding treatment for the base material. The adhesive layer is not limited in particular, but usable examples thereof include the following: fine particles of organic materials such as a polyester resin, a polystyrene resin, a polyacrylic ester resin, a polyamide resin, a polyether resin, a polyvinyl acetate resin, a polyethylene resin, a polypropylene resin, a polyvinyl chloride resin, a polyvinyl alcohol resin and a polyvinyl butyral resin; and fine particles of inorganic materials such as silica, alumina, magnesium carbonate, magnesium oxide and titanium oxide.

The heat sensitive transfer recording sheet of the present disclosure contains the compound represented by Formula (1), and accordingly can provide a heat sensitive transfer recording sheet excellent in the chroma and the light resistance.

<Resist Composition for Color Filter, and Color Filter>

Next, a resist composition for the color filter according to the present disclosure (hereinafter also referred to as “the resist composition of the present disclosure”) will be described. The compound represented by Formula (1) is excellent in the chroma, the light resistance and the solubility, and accordingly is preferable as a compound for toning of the resist composition for the color filter. In addition, by using the resist composition of the present disclosure, the color filter excellent in the chroma and the light resistance can be obtained.

The resist composition for the color filter of the present disclosure contains a binder resin, a medium, and the compound of the present disclosure as a colorant. The resist composition for the color filter of the present disclosure is obtained in the following way. The compound of the present disclosure and the binder resin are added to the medium with stirring. At this time, it is acceptable to add a polymerizable monomer, a polymerization initiator, a photoacid generating agent and the like, as needed. Thereafter, a mechanical shearing force is applied to the above mixture with the use of a dispersing machine to stably dissolve or finely disperse the above materials in the medium, and thereby the resist composition for the color filter of the present disclosure can be obtained.

[Binder Resin]

As a binder resin which can be used for the resist composition of the present disclosure, any binder resin is acceptable of which either one of a part irradiated with light or a part shielded from light in an exposure step at the time of pixel formation can be dissolved by an organic solvent, an aqueous alkaline solution, water or a commercially available developing solution. Among the binder resins, a binder resin that has a composition which can be developed by water or the aqueous alkaline solution is preferable, from the viewpoint of workability and ease of processing after the resist has been produced.

As the above binder resin, a binder resin can be used which has been formed by copolymerizing the following hydrophilic polymerizable monomer with the following lipophilic polymerizable monomer at an appropriate mixing ratio, by a known method.

The hydrophilic polymerizable monomers: a polymerizable monomer and the like, which has acrylic acid, methacrylic acid, N-(2-hydroxyethyl)acrylamide, N-vinylpyrrolidone or an ammonium salt.

The lipophilic polymerizable monomers: an acrylic acid ester, a methacrylic acid ester, vinyl acetate, styrene, N-vinylcarbazole and the like.

These binder resins are used in combination with a radical polymerizable monomer having an ethylenic unsaturated group, a cationic polymerizable monomer having an oxirane ring or an oxetane ring, a radical generating agent, an acid generating agent and a base generating agent. This type of binder resin lowers the solubility of a material of an exposed portion to a developing solution due to the exposure to light, and accordingly can be used as a negative type of resist composition in which only a portion shielded from light is removed by development.

In addition, a resin can be used that has a quinonediazide group which is cleaved by light and forms a carboxylic acid. Furthermore, a resin can also be used that has a group which is cleaved by an acid, such as tert-butyl carbonate of poly(hydroxystyrene), and tetrahydropyranyl ether, in combination with an acid generating agent which generates an acid by exposure to light. When this type of resin is exposed to light, the solubility of the material of the exposed portion to a developing solution increases, and accordingly the resin can be used as a positive type of resist composition in which only the portion exposed to light is removed by development.

When the resist composition of the present disclosure is the above negative type of resist composition, it is preferable to use a polymerizable monomer which causes addition polymerization by exposure to light (hereinafter also referred to as “photopolymerizable monomer”), as the binder resin. It is preferable that the photopolymerizable monomer is a compound having at least one ethylenic unsaturated double bond which is addition polymerizable in the molecule, and having a boiling point of 100° C. or higher at normal pressure. Specifically, examples thereof include the following: monofunctional acrylates and methacrylates such as polyethylene glycol monoacrylate, polyethylene glycol monomethacrylate, polypropylene glycol monoacrylate, polypropylene glycol monomethacrylate, phenoxyethyl acrylate, and phenoxyethyl methacrylate; polyfunctional acrylates and methacrylates such as polyethylene glycol diacrylate, polyethylene glycol dimethacrylate, polypropylene glycol diacrylate, polypropylene glycol dimethacrylate, trimethylolethane triacrylate, trimethylolethane trimethacrylate, trimethylolpropane triacrylate, trimethylolpropane trimethacrylate, trimethylolpropane diacrylate, trimethylolpropane dimethacrylate, neopentyl glycol diacrylate, neopentyl glycol dimethacrylate, pentaerythritol tetraacrylate, pentaerythritol tetramethacrylate, pentaerythritol triacrylate, pentaerythritol trimethacrylate, dipentaerythritol hexaacrylate, dipentaerythritol hexamethacrylate, dipentaerythritol pentaacrylate, dipentaerythritol pentamethacrylate, hexanediol diacrylate, hexanediol dimethacrylate, trimethylolpropane tri(acryloyloxypropyl) ether, tri(acryloyloxyethyl) isocyanurate, tri(acryloyloxyethyl) cyanurate, glycerin triacrylate, and glycerin trimethacrylate; and polyfunctional acrylates and polyfunctional methacrylates which are obtained by adding ethylene oxide or propylene oxide to a polyfunctional alcohol such as trimethylolpropane and glycerin, and then acrylating or methacrylating the above resultant adduct. Furthermore, urethane acrylates, polyester acrylates, polyfunctional epoxy acrylates or epoxy methacrylates can also be used which are reaction products between an epoxy resin and acrylic acid or methacrylic acid.

Among the above photopolymerizable monomers, it is preferable to use the following monomers: trimethylolpropane triacrylate, trimethylolpropane trimethacrylate, pentaerythritol tetraacrylate, pentaerythritol tetramethacrylate, dipentaerythritol hexaacrylate, dipentaerythritol hexamethacrylate, dipentaerythritol pentaacrylate, and dipentaerythritol pentamethacrylate. The above photopolymerizable monomers may be used singly or in combinations of two or more, as needed.

It is preferable for the content of the above photopolymerizable monomer to be 5% by mass to 50% by mass with respect to the mass (total solid content) of the resist composition according to the present disclosure, and is more preferable to be 10% by mass to 40% by mass. When the above content is 5% by mass to 50% by mass, the sensitivity to exposure to light can be further enhanced and the tackiness of the resist composition can also become good.

When the resist composition of the present disclosure is the above negative type of resist composition, a photopolymerization initiator may be added. The photopolymerization initiators include a vicinal poly-keto aldol compound, an α-carbonyl compound, acyloin ether, quinone compounds, a combination of triallylimidazole dimer and p-aminophenyl ketone, and a trioxadiazole compound. Among the photopolymerization initiators, 2-benzyl-2-dimethylamino-1-(4-morpholinophenyl) butanone (trade name: Irgacure 369, manufactured by BASF) is preferable. Note that in the case where an electron beam is used when pixels are formed by the resist composition of the present disclosure, the above photopolymerization initiator is not essential.

In addition, when the resist composition of the present disclosure is the above positive type of resist composition, a photoacid generating agent may be added as necessary. As the photoacid generating agent, such known photoacid generating agents can be used as salts between onium ions such as sulfonium, iodonium, selenium, ammonium and phosphonium, and anions.

The above sulfonium ions include the following: triphenyl sulfonium, tri-p-tolyl sulfonium, tri-o-tolyl sulfonium, tris(4-methoxyphenyl) sulfonium, 1-naphthyldiphenyl sulfonium, diphenylphenacyl sulfonium, phenylmethylbenzyl sulfonium, 4-hydroxyphenyl methylbenzyl sulfonium, dimethylphenacyl sulfonium, and phenacyl tetrahydrothiophenium.

The above iodonium ions include diphenyl iodonium, di-p-tolyl iodonium, bis(4-dodecylphenyl) iodonium, bis(4-methoxyphenyl) iodonium, and (4-octyloxyphenyl) phenyl iodonium.

The above selenium ions include the following: triaryl selenium such as triphenyl selenium, tri-p-tolyl selenium, tri-o-tolyl selenium, tris(4-methoxyphenyl) selenium, 1-naphthyldiphenyl selenium, tris(4-fluorophenyl) selenium, tri-1-naphthyl selenium, and tri-2-naphthyl selenium.

The above ammonium ions include the following: tetraalkylammonium such as tetramethylammonium, ethyltrimethylammonium, diethyldimethylammonium, triethylmethylammonium, tetraethylammonium, trimethyl-n-propylammonium, trimethyli sopropylammonium, trimethyl-n-butylammonium, and trimethylisobutylammonium.

The above phosphonium ions include the following: tetraphenyl phosphonium, tetra-p-tolyl phosphonium, tetrakis(2-methoxyphenyl) phosphonium, triphenylbenzyl phosphonium, triphenylphenacyl phosphonium, triphenylmethyl phosphonium, triethylbenzyl phosphonium, and tetraethyl phosphonium.

The above anions include the following: perhalogenate ions such as ClO₄⁻ and BrO₄⁻; halogenated sulfonate ions such as FSO₃⁻ and ClSO₃⁻; sulfate ions such as CH₃SO₄⁻, CF₃SO₄⁻ and HSO₄⁻; carbonate ions such as HCO₃⁻ and CH₃CO₃⁻; aluminate ions such as AlCl₄⁻ and AlF₄⁻; hexafluorobismuthate ions; carboxylate ions such as CH₃COO⁻, CF₃COO⁻, C₆H₅COO, CH₃C₆H₄COO⁻, C₆F₅COO⁻ and CF₃C₆H₄COO⁻; aryl borate ions such as B(C₆H₅)₄⁻ and CH₃CH₂CH₂CH₂B(C₆H₅)₃⁻; and thiocyanate ions and nitrate ions. However, the anions are not limited to these anions.

[Medium]

In the resist composition of the present disclosure, water or an organic solvent can be used as a medium for dissolving or dispersing the following therein: the compound of the present disclosure; the binder resin; and the photopolymerizable monomer, photopolymerization initiator and photoacid generating agent which are added as needed. The organic solvents include the following: cyclohexanone, ethyl cellosolve acetate, butyl cellosolve acetate, 1-methoxy-2-propyl acetate, diethylene glycol dimethyl ether, ethyl benzene, 1,2,4-trichlorobenzene, ethylene glycol diethyl ether, xylene, ethyl cellosolve, methyl-n-amyl ketone, propylene glycol monomethyl ether, toluene, methyl ethyl ketone, ethyl acetate, methanol, ethanol, isopropanol, butanol, methyl isobutyl ketone, and petroleum-based solvents. These solvents may be used singly or in combinations of two or more.

[Colorant]

As the colorant constituting the resist composition of the present disclosure, the compound represented by Formula (1) is used, and the compounds may be used singly or in combinations of two or more. In addition, in order to obtain desired spectral characteristics, other dyes may be used in combination as the application for toning. The dyes which can be used in combination are not limited in particular, but include the following: a condensed azo compound, a metal azo complex, a diketopyrrolopyrrole compound, an anthraquinone compound, a quinacridone compound, a naphthol compound, a benzimidazolone compound, a thioindigo compound, a perylene compound, a methine compound, an arylamide compound, and a lake compound of basic dye.

In addition to the above additives, it is also acceptable to add an ultraviolet absorber, and a silane coupling agent of which the purpose is to enhance the adhesiveness to a glass substrate at the time of filter production, to the resist composition for the color filter of the present disclosure, as needed.

The dispersing machine is not limited in particular, but media type dispersing machines such as a rotary shear type homogenizer, a ball mill, a sand mill and an attritor, and a high-pressure opposed collision type of dispersing machine can be used.

As described above, the resist composition for the color filter of the present disclosure contains the compound represented by Formula (1), the resist composition for color filter becomes excellent in the chroma and the light resistance. In a color filter in which two or more pixels having different spectral characteristics are arranged adjacent to each other, the resist composition of the present disclosure is used for pixels constituting at least one color among the plurality of colors (for example, red, green, and blue) of the pixels. By such configuration, a color filter excellent in the chroma and the light resistance can be obtained.

<Toner>

Next, the toner according to the present disclosure will be described. The compound of the present disclosure is excellent in the chroma, the light resistance and the solubility, and accordingly can be preferably used for the toner.

The toner of the present disclosure includes: a compound represented by Formula (1) as a colorant; a binder resin; and conventionally used pigment for toner, magnetic body, wax, charge control agent and other additives, as needed. Methods for producing a toner particle constituting the toner of the present disclosure include a pulverization method, a suspension polymerization method, a suspension granulation method, an emulsion polymerization method and an emulsion aggregation method. The toner can also be used as a developing agent which is used in a liquid development method. It is preferable that the toner of the present disclosure, which uses the compound represented by Formula (1) as the colorant, is a pulverized toner produced by the pulverization method, among the methods.

As the colorant, the compound represented by Formula (1) is used, and the compounds may be used singly or in combinations of two or more. In addition, the compound represented by Formula (1) can be used in combination with a known pigment or dye, in order to adjust the color tone or the like, according to the method for producing the toner.

One example of the method for producing the pulverized toner will be described below.

[Method for Producing Pulverized Toner]

The pulverized toner is produced by melting and kneading a colorant and the like in a binder resin; uniformly dispersing the melted and kneaded product; then cooling and solidifying the resultant melted and kneaded product; pulverizing the resultant kneaded product with a pulverizer; and classifying the pulverized product with a classifying machine to obtain toner particles having a desired particle size. Specifically, firstly, materials are sufficiently mixed that include: the compound represented by Formula (1) as a colorant; a binder resin; and a pigment for toner, a magnetic body and wax, a charge control agent and other additives which are conventionally used, as needed, with the use of a blending machine such as a Henschel mixer or a ball mill. Next, the mixture is melted with the use of a thermal kneading machine such as a roll, a kneader and an extruder. Furthermore, the resins are mixed with each other by being milled and kneaded, and then the wax and/or the magnetic body are added thereto and are dispersed therein, as needed. Then, the dispersion is cooled and solidified, the solid is pulverized and classified, and the pulverized toner can be obtained. For the production of the pulverized toner, a known production apparatus such as a blending machine, a thermal kneading machine and a classifying machine can be used. Each component constituting the toner will be described below.

[Colorant]

As the colorant, a conventionally used pigment for toner (for example, C. I. Pigment Blue 15:3) and a compound represented by Formula (1) are used. As describe above, the compounds may be used singly or in combinations of two or more. In addition, colorants such as a well-known dye or pigment can also be used in combination, as needed.

When the pigment is used in combination, the compound represented by Formula (1) can be used in a range of 0.01 times by mass to 1.0 time by mass with respect to the pigment to be used in combination, preferably 0.03 times by mass to 0.5 times by mass, and particularly preferably 0.05 times mass to 0.2 times by mass.

The colorants that can be used in combination are not limited in particular, but include the following: a condensed azo compound, a metal azo complex, a diketopyrrolopyrrole compound, an anthraquinone compound, a quinacridone compound, a naphthol compound, a benzimidazolone compound, a thioindigo compound, a perylene compound, a methine compound, an allyl amide compound, and a lake compound of basic dye.

[Binder Resin]

The binder resins which are used for the toner of the present disclosure include the following: a vinyl resin, a polyester resin, an epoxy resin, a polyurethane resin, a polyvinyl butyral resin, a terpene resin, a phenol resin, an aliphatic or alicyclic hydrocarbon resin, an aromatic petroleum resin, a rosin and a modified rosin. Among the above resins, the vinyl resin and the polyester resin are preferable from the viewpoint of chargeability and fixability, and the use of polyester resins is more preferable because in the case, the effects of the chargeability and the fixability are further increased. These resins may be used singly or in combinations of two or more. When two or more resins are mixed and used, it is preferable to mix resins having different molecular weights, in order to control the viscoelastic properties of the toner.

As for the above binder resin, it is preferable for a glass transition temperature (Tg) thereof to be 45° C. or higher and 80° C. or lower, and is more preferable to be 55° C. to 70° C. In addition, it is preferable that the number average molecular weight (Mn) is 1,500 to 50,000, and that the weight average molecular weight (Mw) is 6,000 to 1,000,000.

When the polyester resin is used as the binder resin, the polyester resin is not limited in particular, but is preferably a resin of which the molar ratio of alcohol component/acid component in all components is 45/55 to 55/45. As for the polyester resin, as the number of terminal groups of the molecular chain increases, the environmental dependency in the charging characteristics of the toner increases. Because of this, it is preferable for the acid value to be 90 mgKOH/g or smaller, and is more preferable to be 50 mgKOH/g or smaller. In addition, it is preferable for the hydroxyl value to be 50 mgKOH/g or smaller, and is more preferable to be 30 mgKOH/g or smaller.

[Wax]

To the toner of the present disclosure, a wax may be added, as needed. The waxes include polyethylene wax, paraffin wax and fatty acid ester wax; but are not limited to these waxes.

[Charge Control Agent]

In the toner of the present disclosure, a charge control agent may be mixed, as needed. The charge control agent is not limited in particular, but examples of an agent which control the toner so as to be negatively charged include the following: a polymer or a copolymer which has a sulfonic acid group, a sulfonate group or a sulfonic acid ester group; a salicylic acid derivative and metal complexes thereof, a monoazo metal compound, an acetylacetone metal compound, an aromatic oxycarbonic acid, aromatic mono- and poly-carboxylic acids, and metal salts, anhydrides and esters thereof; and phenol derivatives such as bisphenol, a urea derivative, a metal-containing naphthoic acid-based compound, a boron compound, a quaternary ammonium salt, calixarene, and a resin-based charge control agent.

In addition, examples of an agent which control the toner so as to be positively charged include the following: a nigrosine modified product by nigrosine and a fatty acid metal salt or the like, a guanidine compound, an imidazole compound, tributylbenzylammonium-1-hydroxy-4-naphthosulfonate, a quaternary ammonium salt such as tetrabutylammonium tetrafluoroborate, and onium salts such as a phosphonium salt, which are analogs thereof, and lake pigments thereof; triphenylmethane dyes and lake pigments thereof (where laking agents include phosphotungstic acid, phosphomolybdic acid, phosphotungstic-molybdic acid, tannic acid, lauric acid, gallic acid, ferricyanide and ferrocyanide); and a metal salt of a higher fatty acid, diorganotin oxides such as dibutyltin oxide, dioctyltin oxide and dicyclohexyltin oxide, diorganotin borates such as dibutyltin borate, dioctyltin borate and dicyclohexyltin borate, and a resin-based charge control agent.

These charge control agents may be used singly or in combinations of two or more.

### EXAMPLES

The present disclosure will be described in more detail below with reference to Examples and Comparative Examples, but the technical scope of the present disclosure is not limited to these Examples. In the text, “part” means “part by mass” unless otherwise specified. The obtained compound was identified with the use of a ¹H-nuclear magnetic resonance spectroscopic analysis (¹H-NMR) apparatus (AVANCE-600 NMR spectrometer, manufactured by Bruker Japan K.K.), and a high-performance liquid chromatograph-mass spectrometer (LCMS-2010, manufactured by Shimadzu Corporation).

### Production Example 1: Production of Compound (1-2)

A mixed solution was cooled to 0° C., which contained a triazole compound (A-1) (4.25 g, 18.4 mmol), 48 mL of acetic acid, 12 mL of water, and 12 mL of concentrated hydrochloric acid, and a solution of sodium nitrite (1.27 g, 18.4 mmol) in 2 mL of water was slowly added dropwise while the temperature was kept at 5° C. or lower. Then, the mixture was stirred at 0 to 5° C. for 1 hour. Furthermore, the mixture was warmed to room temperature, and was stirred for 1 hour. The precipitated solid was filtered and washed with 200 mL of water, and a nitroso compound (2.58 g, yield 60.7%) was obtained.

A thiazole compound (C-1) (2.32 g, 5.6 mmol) was added to a solution of the obtained nitroso compound (1.5 g, 5.6 mmol) in 80 mL of chloroform, and the mixture was stirred at room temperature for 24 hours. After the completion of the reaction, the solvent was concentrated under a reduced pressure, the concentrate was purified by silica gel column chromatography (developing solvent: ethyl acetate/heptane), and a compound (1-2) (1.19 g, 32.5%) was obtained. The compound (1-2) was identified by the ¹H-NMR analysis and mass spectrometry.

[Analysis Result of Compound (1-2)]

[1] ¹H-NMR (600 MHz, by solvent of CDCl₃, at room temperature): δ (ppm)=0.87-0.99 (15H, m), 1.25-1.42 (12H, m), 1.52-1.95 (4H, m), 1.98-2.10 (2H, m), 2.48 (3H, s), 2.50 (3H, s), 2.52 (3H, s), 3.60 (2H, br), 3.90-4.08 (2H, br), 4.20-4.39 (2H, br), 7.37 (2H, d, J=8.4 Hz), and 7.77 (2H, d, J=8.4 Hz).

[2] Mass spectrometry (LCMS-2010): m/z=656.55 (M+H)⁺.

### Production Example 2: Production of Compound (1-5)

A compound (1-5) was produced in the same method as in Production Example 1, except that a triazole compound (A-4) was used instead of the triazole compound (A-1), and was identified.

[Analysis Result of Compound (1-5)]

[1] ¹H-NMR (600 MHz, with solvent of CDCl₃ at room temperature): δ (ppm)=0.99-1.09 (12H, m), 1.11-1.12 (3H, m), 1.31-1.60 (18H, m), 2.08-2.14 (1H, br), 2.16-2.27 (1H, br), 2.58 (2H, s), 2.68 (3H, s), 3.10 (2H, br), 3.70-3.80 (2H, m), 4.01-4.10 (1H, m), 4.11-4.20 (1H, m), 7.02 (1H, s), 7.57 (2H, t, J=7.8 Hz), 7.76 (1H, s), and 8.43 (2H, d, J=7.2 Hz).

[2] Mass spectrometry (LCMS-2010): m/z=672.45 (M+H)⁺.

### Production Example 3: Production of Compound (1-6)

A compound (1-6) was produced in the same method as in Production Example 1, except that a triazole compound (A-4) was used instead of the triazole compound (A-1) and a thiazole compound (C-5) was used instead of the thiazole compound (C-1), and was identified.

[Analysis Result of Compound (1-6)]

[1] ¹H-NMR (600 MHz, with solvent of CDCl₃ at room temperature): δ (ppm)=0.88-1.00 (12H, m), 1.25-1.50 (20H, m), 1.98 (2H, br), 2.09 (2H, br), 2.49 (3H, s), 2.50 (3H, s), 2.51 (3H, s), 3.59 (2H, m), 3.98-4.07 (2H, m), 6.49 (1H, br), 7.37 (2H, d, J=7.8 Hz), and 8.49 (2H, d, J=8.4 Hz).

[2] Mass spectrometry (LCMS-2010): m/z=672.45 (M+H)⁺.

### Production Example 4: Production of Compound (1-7)

A compound (1-7) was produced in the same method as in Production Example 1, except that a triazole compound (A-7) was used instead of the triazole compound (A-1), and was identified.

[Analysis Result of Compound (1-7)]

[1] ¹H-NMR (600 MHz, with solvent of CDCl₃ at room temperature): δ (ppm)=0.87-1.01 (12H, m), 1.26-1.50 (18H, m), 2.64 (3H, s), 3.62 (2H, m), 3.92-4.07 (2H, m), 7.1 (1H, s), 7.22-7.39 (6H, m), 7.50-7.59 (4H, m), 7.61-7.72 (2H, m), and 8.32 (2H, d, J=7.8 Hz).

[2] Mass spectrometry (LCMS-2010): m/z=672.45 (M+H)⁺.

<Production of Ink>

The inks of the present disclosure and comparative inks were produced by methods described below.

### Example 1: Production of Ink (1)

To a mixed solution of 45 parts of methyl ethyl ketone and 45 parts of toluene, 5 parts of a polyvinyl butyral resin (Denka 3000-K; manufactured by Denki Kagaku Kogyo Co., Ltd.) were gradually added and dissolved. To the above resultant solution, 5 parts of compound (1-2) synthesized in Production Example 1 was added and dissolved, and thereby a cyan ink (1) was obtained.

### Examples 2 to 4: Production of Inks (2) to (4)

Inks (2) to (4) were produced in the same manner as in Example 1, except that in Example 1, the compound (1-2) was changed to the respective compounds shown in Table 1.

### Examples 5 to 7: Production of Inks (5) to (7)

Inks (5) to (7) were produced in the same manner as in Example 1, except that instead of 5 parts of the compound (1-2) used in Example 1, the following compounds were added at the following mixing ratios.

### Example 5: 4 Parts of the Compound (1-2) and 1 Part of a Compound (1-7)

### Example 6: 2.5 Parts of the Compound (1-2) and 2.5 Parts of the Compound (1-7)

### Example 7: 1 Part of the Compound (1-2) and 4 Parts of the Compound (1-7)

### Comparative Examples 1 to 6: Production of Comparative Inks (1) to (6)

Comparative inks (1) to (6) were produced in the same manner as in Example 1, except that in Example 1, the compound (1-2) was changed to the following comparative compounds (D-1) to (D-6), respectively.

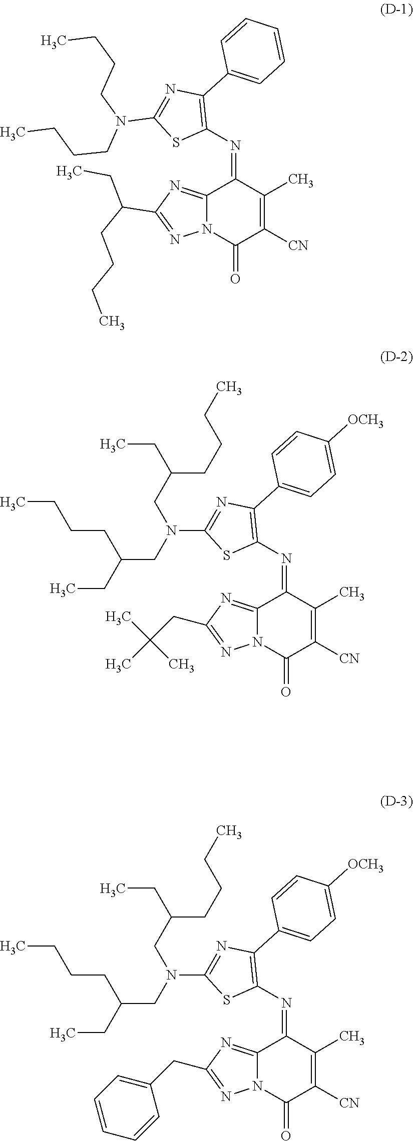 [SMILES: CCCCC(CC)c1nc2n(n1)C(=O)C(C#N)=C(C)/C2=N/c1sc(N(CCCC)CCCC)nc1-c1ccccc1 ; CCCCC(CC)CN(CC(CC)CCCC)c1nc(-c2ccc(OC)cc2)c(/N=C2/C(C)=C(C#N)C(=O)n3nc(CC(C)(C)C)nc32)s1 ; CCCCC(CC)CN(CC(CC)CCCC)c1nc(-c2ccc(OC)cc2)c(/N=C2/C(C)=C(C#N)C(=O)n3nc(Cc4ccccc4)nc32)s1]

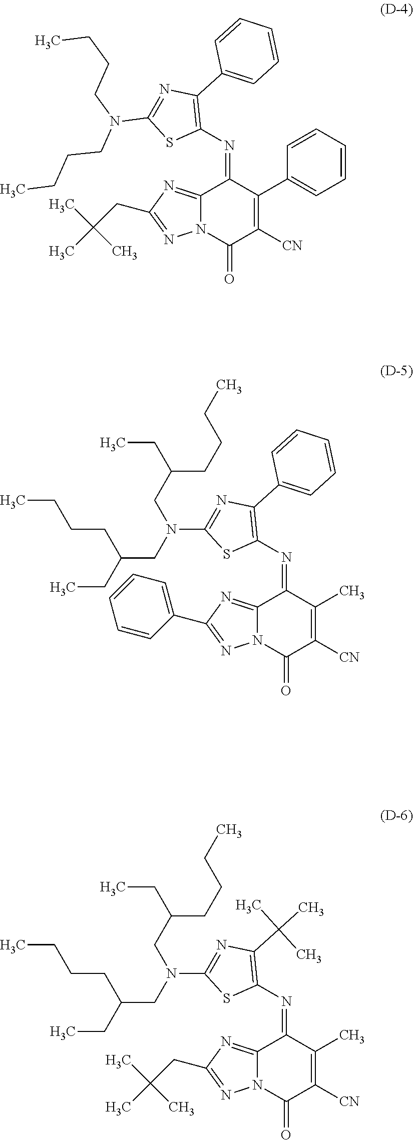 [SMILES: CCCCN(CCCC)c1nc(-c2ccccc2)c(/N=C2/C(c3ccccc3)=C(C#N)C(=O)n3nc(CC(C)(C)C)nc32)s1 ; CCCCC(CC)CN(CC(CC)CCCC)c1nc(-c2ccccc2)c(/N=C2/C(C)=C(C#N)C(=O)n3nc(-c4ccccc4)nc32)s1 ; CCCCC(CC)CN(CC(CC)CCCC)c1nc(C(C)(C)C)c(/N=C2/C(C)=C(C#N)C(=O)n3nc(CC(C)(C)C)nc32)s1]

[Production of Heat Sensitive Transfer Recording Sheet and Image Sample]

The heat sensitive transfer recording sheet which used the ink of the present disclosure was produced by applying the above cyan ink (1) to a polyethylene terephthalate film (Lumirror®; manufactured by Toray Industries, Inc.) having a thickness of 4.5 μm so that the thickness after drying became 1 μm, and drying the applied ink.

Thus formed heat sensitive transfer recording sheet was transferred onto photographic paper with the use of a modified machine of Selfy CP1300 (compact photo printer manufactured by Canon Inc.), and an image sample (1) was produced.

[Evaluation of Chroma]

For each of the produced image samples, the lightness (L*) and the chromaticity (a* and b*) in the L*a*b* colorimetric system were measured with the use of a spectral densitometer (fluorescence spectral densitometer FD-7, manufactured by Konica Minolta Inc.), and the chroma (C*) was calculated according to the following expression.

C*=\sqrt{(a*)²+(b*)²}

It can be deemed that the larger the chroma C* and the lightness L* are, the better the extension of the chroma is, and the higher the chroma is. The results are shown in Table 1.

The evaluation criteria are as follows.

A: L* is 50.0 or larger and C* is 65.0 or larger

B: L* is 40.0 or larger and smaller than 50.0, and C* is 65.0 or larger

C: L* is smaller than 40.0, or C* is smaller than 65.0

[Evaluation of Aggregation Properties]

Each of the produced image samples was visually observed at a magnification of 400 times with the use of a phase contrast microscope (BX53, manufactured by Olympus Corporation), and the presence or absence of aggregates was observed.

A: The image sample has no aggregate and is good.

B: A slight amount of aggregates are formed in the image sample.

C: Aggregates are formed in the image sample.

[Evaluation of Light Resistance]

The above image sample was charged into a xenon test apparatus (Atlas Weather O-meter Ci4000, manufactured by Toyo Seiki Seisaku-sho, Ltd.), and was exposed under the conditions (illuminance: 0.28 W/m² at 340 nm, black panel temperature: 40° C., and relative humidity: 50%) for 5 hours. When the initial optical density was represented by OD₀ and the O.D. after exposure of 5 hours was represented by OD₅, a residual ratio of the O.D. was defined as follows.

Residual ratio of O.D. (%)=(OD₅/OD₀)×100

The evaluation criteria are as follows.

A: 85≤Residual ratio of O.D. (%)

B: 70≤Residual ratio of O.D. (%)<85

C: Residual ratio of O.D. (%)<70

TABLE 1

| | | | | | | | Evaluation of | Residual | Evaluation |
|---|---|---|---|---|---|---|---|---|---|
| | | Number | | | | Evaluation | aggregation | ratio of O.D. | of light |
| | Compound used | of parts | Ink | c* | L* | of chroma | properties | after 5 hours | resistance |
| Example 1 | Compound (1-2) | 5 parts | Ink (1) | 65.8 | 62.5 | A | A | 86% | A |
| Example 2 | Compound (1-5) | 5 parts | Ink (2) | 66.3 | 63.7 | A | A | 85% | A |
| Example 3 | Compound (1-6) | 5 parts | Ink (3) | 65.4 | 64.5 | A | A | 87% | A |
| Example 4 | Compound (1-7) | 5 parts | Ink (4) | 65.7 | 47.8 | B | B | 80% | B |
| Example 5 | Compound (1-2)/ | 4 parts/ | Ink (5) | 65.8 | 59.5 | A | A | 85% | A |
| | Compound (1-7) | 1 part | | | | | | | |
| Example 6 | Compound (1-2)/ | 2.5 parts/ | Ink (6) | 65.8 | 55.2 | A | A | 83% | B |
| | Compound (1-7) | 2.5 parts | | | | | | | |
| Example 7 | Compound (1-2)/ | 1 part/ | Ink (7) | 65.7 | 50.7 | A | B | 82% | B |
| | Compound (1-7) | 4 parts | | | | | | | |
| Comparative | Comparative | 5 parts | Comparative | 76.3 | 47.6 | B | C | 79% | B |
| Example 1 | compound (D-1) | | ink (1) | | | | | | |
| Comparative | Comparative | 5 parts | Comparative | 70.0 | 60.1 | A | C | 77% | B |
| Example 2 | compound (D-2) | | ink (2) | | | | | | |
| Comparative | Comparative | 5 parts | Comparative | 71.3 | 59.5 | A | C | 75% | B |
| Example 3 | compound (D-3) | | ink (3) | | | | | | |
| Comparative | Comparative | 5 parts | Comparative | 73.0 | 50.4 | A | C | 69% | C |
| Example 4 | compound (D-4) | | ink (4) | | | | | | |
| Comparative | Comparative | 5 parts | Comparative | 60.4 | 63.2 | A | C | 60% | C |
| Example 5 | compound (D-5) | | ink (5) | | | | | | |
| Comparative | Comparative | 5 parts | Comparative | 52.2 | 54.2 | C | B | 40% | C |
| Example 6 | compound (D-6) | | ink (6) | | | | | | |

As shown in Table 1, it has been found that the inks of Examples, which contain the compound represented by the Formula (1), were excellent in the chroma, the light resistance and the solubility, compared to the comparative inks.

<Production of Color Filter>

A resist composition for a color filter and the color filter were produced by a method to be described below.

### Example 8

To 12 parts of the compound (1-2) synthesized in Production Example 1, 120 parts of cyclohexanone was mixed, and was dispersed for 1 hour by the use of an attritor (manufactured by Mitsui Mining Co., Ltd.) and thereby an ink (1) for the resist composition was obtained.

Subsequently, 22 parts of the above ink (1) for the resist composition was slowly added to a mixed solution of the following materials, and the mixture was stirred at room temperature for 3 hours.

6.7 parts of an acrylic copolymer composition (weight average molecular weight Mw: 10,000) of which the monomer ratio is: 40% by mass of n-butyl methacrylate, 30% by mass of acrylic acid, and 30% by mass of hydroxyethyl methacrylate

1.3 parts of dipentaerythritol pentaacrylate

0.4 parts of 2-benzyl-2-dimethylamino-1-(4-morpholinophenyl)-butanone (photopolymerization initiator)

96 parts of cyclohexanone

The mixture was filtered by the use of a filter having a pore size of 1.5 μm and a resist composition (1) for a color filter was obtained.

A glass substrate was spin-coated with the above resist composition (1) for the color filter, the above resist composition (1) was dried at a temperature of 90° C. for 3 minutes, then the whole surface of the dried film was exposed to light, the exposed surface was post-cured at a temperature of 180° C., and the color filter (1) was produced.

### Examples 6 to 8

Resist compositions (2) to (4) for a color filter were obtained in the same manner as in Example 8, except that the compound (1-2) was changed to the respective compounds shown in Table 2. In addition, color filters (2) to (4) were produced in the same manner as in Example 8, except that the obtained resist compositions (2) to (4) for the color filter were used, respectively, in place of the resist composition (1) for the color filter.

### Comparative Examples 7 to 12

Resist compositions (1) to (6) for a comparative color filter were obtained in the same manner as in Example 8, except that the compound (1-2) was changed to comparative compounds (D-1) to (D-6), respectively. In addition, comparative color filters (1) to (6) were produced in the same manner as in Example 8, except that the obtained resist compositions (1) to (6) for the comparative color filter were used in place of the resist composition (1) for the color filter.

[Evaluation of Chroma and Hue]

A white PET film was laid under each color filter, and the lightness (L*) and chromaticity (a*, b*) in the L*a*b* colorimetric system were measured with the use of a spectral densitometer (fluorescence spectral densitometer FD-7, manufactured by Konica Minolta, Inc.), and the chroma (C*) was calculated according to the above expression. Evaluation criteria based on the lightness (L*) and the chroma (C*) are the same as in Examples 1 to 4.

[Evaluation of Light Resistance]

The above image sample was charged into a xenon test apparatus (Atlas Weather O-meter Ci4000, manufactured by Toyo Seiki Seisaku-sho, Ltd.), and was exposed under the conditions (illuminance: 0.36 W/m² at 340 nm, black panel temperature: 50° C., and relative humidity: 50%) for 5 hours. When the initial optical density was represented by OD₀ and the O.D. after exposure of 5 hours was represented by OD₅, a residual ratio of the O.D. was defined as follows.

Residual ratio of O.D. (%)=(OD₅/OD₀)×100

The evaluation criteria are as follows.

A: 85<Residual ratio of O.D. (%)

B: 70<Residual ratio of O.D. (%)≤85

C: Residual ratio of O.D. (%)≤70

The obtained results are shown in Table 2.

TABLE 2

| | | | | | | Evaluation of | Residual | Evaluation |
|---|---|---|---|---|---|---|---|---|
| | | | | | Evaluation | aggregation | ratio of O.D. | of light |
| | Compound used | Application | c* | L* | of chroma | properties | after 5 hours | resistance |
| Example 8 | Compound (1-2) | Color filter (1) | 65.7 | 62.1 | A | A | 86% | A |
| Example 9 | Compound (1-5) | Color filter (2) | 65.8 | 63.2 | A | A | 85% | A |
| Example 10 | Compound (1-6) | Color filter (3) | 65.2 | 63.7 | A | A | 87% | A |
| Example 11 | Compound (1-7) | Color filter (4) | 65.0 | 47.2 | B | B | 80% | B |
| Comparative | Comparative | Comparative | 75.2 | 47.5 | B | C | 78% | B |
| Example 7 | compound (D-1) | color filter (1) | | | | | | |
| Comparative | Comparative | Comparative | 68.9 | 58.8 | A | C | 77% | B |
| Example 8 | compound (D-2) | color filter (2) | | | | | | |
| Comparative | Comparative | Comparative | 70.5 | 58.7 | A | C | 76% | B |
| Example 9 | compound (D-3) | color filter (3) | | | | | | |
| Comparative | Comparative | Comparative | 72.2 | 48.7 | B | C | 68% | C |
| Example 10 | compound (D-4) | color filter (4) | | | | | | |
| Comparative | Comparative | Comparative | 58.8 | 62.5 | C | C | 60% | C |
| Example 11 | compound (D-5) | color filter (5) | | | | | | |
| Comparative | Comparative | Comparative | 51.8 | 53.4 | C | B | 38% | C |
| Example 12 | compound (D-6) | color filter (6) | | | | | | |

<Production of Toner>

A toner was produced by a method to be described below.

### Example 12

Binder resin (polyester resin): 100 parts

(Tg: 55° C., acid value: 20 mgKOH/g, hydroxyl value: 16 mgKOH/g, molecular weight of main peak Mp of 4,500, number average molecular weight Mn of 2,300, and weight average molecular weight Mw of 38,000)

C. I. Pigment Blue 15:3: 5 parts

Compound (1-2): 0.5 parts

(1,4-di-t-butyl salicylic acid) aluminum compound: 0.5 parts

Paraffin wax (maximum endothermic peak temperature of 78° C.): 5 parts

The above materials were well mixed by the use of a Henschel mixer (trade name: FM-75J, manufactured by Mitsui Mining Co., Ltd.). Thereafter, the mixture was kneaded at an amount of feed of 60 kg/hr by a twin-screw kneading machine (trade name: PCM-45 model, manufactured by Ikegai Corp.) which was set at a temperature of 130° C. The temperature of the kneaded material at the time when being discharged was approximately 150° C. The obtained kneaded product was cooled and coarsely crushed with a hammer mill, and then was finely pulverized with a mechanical pulverizer (trade name: T-250, manufactured by Turbo Kogyo Co., Ltd.) at an amount of feed of 20 kg/hr. Furthermore, the obtained finely pulverized product was classified by the use of a multi-division classifying machine which uses the Coanda effect, and thereby a toner particle was obtained.

Two parts of a silica fine particle were externally added to 100 parts of the obtained toner particle by the use of a Henschel mixer, and a toner (1) was obtained. As for the obtained toner, a weight average particle size (D4) was approximately 6.3 μm, particles having a particle size of 4.1 μm or smaller were 30.5% by number, and particles having a particle size of 10.1 μm or larger were 0.8% by volume.

A fixed image on which the above toner was mounted in an amount of 0.45 mg/cm² was produced on CLC color copy paper (manufactured by Canon Inc.) by the use of a modified machine of LBP-5300 (trade name, manufactured by Canon Inc.). The lightness (L*) and the chromaticity (a*, b*) in the L*a*b* colorimetric system of the obtained image were measured with the use of the spectral densitometer (fluorescence spectral densitometer FD-7, manufactured by Konica Minolta Inc.), and the chroma (C*) was calculated according to the above expression. An image was obtained of which the chroma was as high as C*=64 and L*=50.6.

The above image was subjected to the light resistance test similar to the above description, and as a result, the residual ratio (%) of O.D. was 95% or more.

### Example 13

A toner was produced in the same method as in Example 12 and a toner particle was obtained, except that in Example 12, 4.5 parts of the C. I. Pigment Blue 15: 3 was used in place of 5 parts of the C. I. Pigment Blue 15:3, and 1.0 part of the compound (1-7) was used in place of the compound (1-2). Two parts of a silica fine particle were externally added to 100 parts of the obtained toner particle by the use of a Henschel mixer, and a toner (2) was obtained. As for the obtained toner, a weight average particle size (D4) was approximately 6.4 μm, particles having a particle size of 4.1 μm or smaller were 30% by number, and particles having a particle size of 10.1 μm or larger were 1.0% by volume.

A fixed image on which the above toner was mounted in an amount of 0.45 mg/cm² was produced on CLC color copy paper (manufactured by Canon Inc.) by the use of a modified machine of LBP-5300 (trade name, manufactured by Canon Inc.). The lightness (L*) and the chromaticity (a*, b*) in the L*a*b* colorimetric system of the obtained image were measured with the use of the spectral densitometer (fluorescence spectral densitometer FD-7, manufactured by Konica Minolta Inc.), and the chroma (C*) was calculated according to the above expression. An image was obtained of which the chroma was as high as C*=63 and L*=51.2.

The above image was subjected to the light resistance test similar to the above description, and as a result, the residual ratio (%) of O.D. was 95% or more.

The compound of the present disclosure is characterized by becoming a compound excellent in the chroma, the light resistance and the solubility. The compound of the present disclosure can be preferably used as the ink, the resist composition for the color filter, the heat sensitive transfer recording sheet, and the colorant of the toner.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-201044, filed Oct. 25, 2018, which is hereby incorporated by reference herein in its entirety.

What is claimed is:

1. A compound having a structure represented by Formula (1): 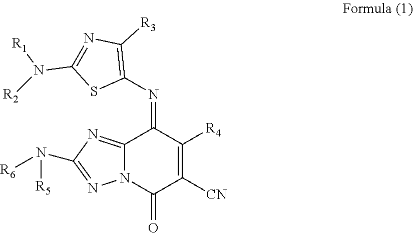
wherein R₁ and R₂ each independently represent a linear or branched alkyl group having 1 to 12 carbon atoms,
R₃ represents a linear or branched alkyl group having 1 to 4 carbon atoms, an aryl group having a substituent, or an unsubstituted aryl group,
R₄ represents an alkyl group having 1 to 4 carbon atoms, and
R₅ and R₆ satisfy the following specifications (i) or (ii):
(i) R₅ and R₆ each independently represent a linear, branched or cyclic alkyl group having 1 to 8 carbon atoms, an alkyl group having a hydroxyl group at the terminal, an aryl group having a substituent, or an unsubstituted aryl group; and
(ii) R₅ and R₆ are combined to form a heterocycle, and R₅ and R₆ each represent an atomic group necessary for forming a heterocycle.

2. The compound according to claim 1, wherein R₁ and R₂ in Formula (1) are each a 2-ethylhexyl group.

3. The compound according to claim 1, wherein R₃ in Formula (1) is a phenyl group or a 4-methylphenyl group.

4. An ink comprising a medium and a compound which exists in a dissolved or dispersed state in the medium, wherein the compound is the compound according to claim 1.

5. A resist composition for a color filter, comprising the compound according to claim 1.

6. A color filter comprising the compound according to claim 1.

7. A heat sensitive transfer recording sheet comprising a base material and a coloring material layer formed on the base material, wherein the coloring material layer contains the compound according to claim 1.

8. A toner comprising a binder resin and a colorant, wherein the colorant contains the compound according to claim 1.
